(19) United States
(12) Patent Application Publication
(10) Pub. No.: US 2021/0059049 A1
(43) Pub. Date: Feb. 25, 2021

(54) SPACE EFFICIENT LAYOUT OF PRINTED CIRCUIT BOARD POWER VIAS

(71) Applicant: Dell Products L.P., Round Rock, TX (US)

(72) Inventors: Meng-Ru Tsai, New Taipei City (TW); Ming-Tung Lai, New Taipei City (TW)

(21) Appl. No.: 16/545,028

(22) Filed: Aug. 20, 2019

(51) Int. Cl. H05K 1/11; H05K 1/18; H05K 3/42; H05K 3/00; G06F 1/26; H05K 1/02

(52) U.S. Cl. CPC H05K 1/115; H05K 1/181; H05K 3/42; H05K 3/0047; H05K 3/0005; H05K 2201/09618; H05K 1/0216; H05K 2201/098; H05K 2201/10015; H05K 2201/10166; G06F 1/26

(57) ABSTRACT

A disclosed method for manufacturing a printed circuit board includes creating multiple conductive layers, each including conductive traces for carrying high-speed data signals, and a non-round plated through power via for delivering high current from a switched-mode power source to and between the conductive layers. Creating the power via may include drilling an opening through the multiple conductive layers, the perimeter of which has a flattened oval shape, and plating the walls of the opening to a predetermined plating thickness using a conductive material. The power via may have a lower resistivity than a combined resistivity of multiple round, plated through vias that, together with required spacing between them, have the same footprint as the power via. The space occupied by the power via may be less than a required footprint for multiple round, plated through vias whose combined resistivity equals the resistivity of the power via.

### BACKGROUND

### Field of the Disclosure

This disclosure relates generally to information handling systems and, more particularly, to systems and methods for space efficient layout of printed circuit board power vias in high-speed computing systems.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems may include one or more printed circuit boards (PCBs). High density layout design is the market trend for PCBs in high performance computing products. For example, in laptop computers, desktop computers, and server products, increasing numbers of integrated circuit components are included on a single PCB. The PCB may include a large number of conductive traces to route signals to and between these components. In typical PCB designs, through holes are widely used as vias for signal trace routing transitions between different PCB layers, for power energy delivery between different layers, and for heat dissipation, such as by including one or more vias on a thermal pad beneath a silicon chip. A key design consideration in high-speed computing systems is how to maintain the system with high operation stability by preventing critical signals from being impacted by the noise of a switching power design.

### SUMMARY

In one aspect, a disclosed printed circuit board includes a plurality of conductive layers, each including conductive traces for carrying high-speed data signals, and a power via for delivering current to and between the plurality of conductive layers. The power via includes an opening passing through the plurality of conductive layers, the walls of the opening are plated to a predetermined plating thickness using a conductive material, and the power via has a flattened oval shape in which, when the power via is viewed from a perspective perpendicular to a top-most one of the multiple conductive layers, two straight edges of the perimeter of the power via are parallel to a major axis of an elliptical shape that encompasses the power via and are parallel to each other and two ends of the perimeter of the power via that connect the two straight edges to each other on respective sides of the power via are rounded.

In any of the disclosed embodiments, the power via may have a lower resistivity than a combined resistivity of a plurality of differently shaped plated through vias that, together with required spacing between the differently shaped plated through vias, collectively require a same footprint size as the power via.

In any of the disclosed embodiments, the space occupied by the power via may be less than a required footprint size of a plurality of differently shaped plated through vias whose combined resistivity equals the resistivity of the power via.

In any of the disclosed embodiments, the length of the major axis of the elliptical shape that encompasses the power via may be greater than multiple times the length of a minor axis of the elliptical shape.

In any of the disclosed embodiments, the power via may be located at least as far from each of the conductive traces for carrying the high-speed data signals as a minimum distance defined by spacing rules for layout of the printed circuit board.

In any of the disclosed embodiments, the plurality of conductive layers may be distributed on respective sides of one or more substrate layers of the printed circuit board or between alternating substrate layers of the printed circuit board.

In any of the disclosed embodiments, the power via may be located proximate an output capacitor and one or more MOSFET devices of a voltage regulator on the printed circuit board.

In any of the disclosed embodiments, the source of the current delivered to and between the plurality of conductive layers may be a switched-mode power supply.

In another aspect, a disclosed method is for manufacturing a printed circuit board. In at least some embodiments, the method includes creating multiple conductive layers, each including conductive traces for carrying high-speed data signals, and creating a power via for delivering current to and between the plurality of conductive layers. Creating the power via includes drilling an opening that passes through the plurality of conductive layers, the perimeter of the opening having a flattened oval shape in which, when the power via is viewed from a perspective perpendicular to a top-most one of the multiple conductive layers, two straight edges of the perimeter of the power via are parallel to a major axis of an elliptical shape that encompasses the power via and are parallel to each other, and the two ends of the perimeter of the power via that connect the two straight edges to each other on respective sides of the power via are rounded. Creating the power via also includes plating the walls of the opening to a predetermined plating thickness using a conductive material.

In any of the disclosed embodiments, the plurality of conductive layers may be distributed on respective sides of one or more substrate layers of the printed circuit board or between alternating substrate layers of the printed circuit board.

In any of the disclosed embodiments, creating the power via may further include, prior to drilling the opening, aligning the plurality of conductive layers, drilling the opening may include drilling through the plurality of conductive layers subsequent the aligning, and plating the walls of the opening may include plating through the opening that passes through the plurality of conductive layers subsequent the drilling.

In any of the disclosed embodiments, the power via may have a lower resistivity than a combined resistivity of a plurality of differently shaped plated through vias that, together with required spacing between the differently shaped plated through vias, collectively require a same footprint size as the power via.

In any of the disclosed embodiments, the space occupied by the power via may be less than a required footprint size of a plurality of differently shaped plated through vias whose combined resistivity equals a resistivity of the power via.

In any of the disclosed embodiments, the method may further include, prior to creating the power via, determining a location at which to create the power via on the printed circuit board dependent on predetermined minimum spacing rules for layout of the printed circuit board. The rules may specify one or more of a minimum distance between the power via and conductive traces carrying high-speed data signals, a minimum distance between the power via and conductive traces carrying data signals of signal types other than a high-speed data signal type, and a minimum distance between the power via and a functional element to be mounted on the printed circuit board proximate the power via.

In any of the disclosed embodiments, the predetermined minimum spacing rules may specify a minimum distance between the power via and conductive traces carrying high-speed data signals that is greater than a specified minimum distance between the power via and conductive traces carrying data signals of signal types other than a high-speed data signal type.

In any of the disclosed embodiments, determining the location at which to create the power via may include determining a location proximate an output capacitor and one or more MOSFET devices of a voltage regulator on the printed circuit board or proximate a switched-mode power supply on the printed circuit board.

In yet another aspect, a disclosed information handling system includes a power supply unit, and a printed circuit board including a plurality of conductive layers, each including conductive traces for carrying high-speed data signals, and a power via for delivering current from the power supply unit to and between the plurality of conductive layers. The power via includes an opening passing through the plurality of conductive layers, the walls of the opening are plated to a predetermined plating thickness using a conductive material, and the power via has a flattened oval shape in which, when the power via is viewed from a perspective perpendicular to a top-most one of the multiple conductive layers, two straight edges of the perimeter of the power via are parallel to a major axis of an elliptical shape that encompasses the power via and are parallel to each other, and the two ends of the perimeter of the power via that connect the two straight edges to each other on respective sides of the power via are rounded.

In any of the disclosed embodiments, the power via may have a lower resistivity than a combined resistivity of a plurality of differently shaped plated through vias that, together with required spacing between the differently shaped plated through vias, collectively require a same footprint size as the power via.

In any of the disclosed embodiments, the space occupied by the power via may be less than a required footprint size of a plurality of differently shaped plated through vias whose combined resistivity equals a resistivity of the power via.

In any of the disclosed embodiments, the power via may be located proximate an output capacitor and one or more MOSFET devices of a voltage regulator on the printed circuit board or proximate a switched-mode power supply on the printed circuit board.

### BRIEF DESCRIPTION OF THE DRAWINGS

For a more complete understanding of the present invention and its features and advantages, reference is now made to the following description, taken in conjunction with the accompanying drawings, in which:

FIG. 1 is a block diagram of selected elements of an embodiment of an information handling system;

FIG. 2A is a block diagram illustrating selected elements of an example PCB layout including an array of round, plated through vias;

FIG. 2B illustrates an example layout design rule for the minimum spacing between a pair of adjacent, round, plated through vias;

FIG. 3A is a block diagram illustrating an example power via with a flattened oval shape, according to some embodiments;

FIG. 3B is a block diagram illustrating an example collection of five round vias in a PCB;

FIG. 4A illustrates a model for estimating the resistivity of a round, plated through via;

FIG. 4B illustrates a model for estimating the resistivity of a plated through power via with a flattened oval shape, according to some embodiments; and

FIG. 5 is flow diagram depicting selected elements of a method for manufacturing a printed circuit board, according to some embodiments.

### DESCRIPTION OF PARTICULAR EMBODIMENT(S)

In the following description, details are set forth by way of example to facilitate discussion of the disclosed subject matter. It should be apparent to a person of ordinary skill in the field, however, that the disclosed embodiments are exemplary and not exhaustive of all possible embodiments.

As used herein, a hyphenated form of a reference numeral refers to a specific instance of an element and the un-hyphenated form of the reference numeral refers to the collective or generic element. Thus, for example, widget “72-1” refers to an instance of a widget class, which may be referred to collectively as widgets “72” and any one of which may be referred to generically as a widget “72”.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components or the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such wires, optical fibers, microwaves, radio waves, and other electromagnetic and/or optical carriers; and/or any combination of the foregoing.

As noted above, through holes are widely used as vias for signal trace routing transitions between different PCB layers, for power energy delivery between different layers, and for heat dissipation. However, in some systems, these vias may carry noise energy which may interfere with nearby traces routing critical signals on the PCB. In the worst case, this interference may cause the system to malfunction or the operation of the system to be unstable. Therefore, when designing the layout for a PCB, traces for routing critical signals may be kept farther away from vias carrying noise energy than other types of traces are. In some cases, layout design rules may specify that critical signal routing should be kept at least a predetermined minimum distance from the power vias and ground vias (collectively referred herein to as “power vias”) of a switched-mode power source, where the predetermined minimum distance is greater than a specified minimum distance between the power vias and other types of data signals. For example, power vias carrying current from a switching PWM buck voltage regulator may carry a large amount of noise energy induced by the switching behavior between its upper MOSFET devices and its lower MOSFET devices. In high density layout designs, it may be difficult to keep all of the critical and high-speed signal traces away from any noise carrying vias in accordance with the minimum spacing rules between the signal traces and these vias without adding extra layers in PCB for signal routing with their associated costs in terms of materials and time.

In at least some embodiments of the systems described herein, power vias having a flattened oval shape may occupy less layout space than traditional arrays of small, round vias, while being able to deliver high current energy between different PCB layers. The use of these power vias may reduce interference caused by noise carrying vias by making room for minimum spacing rules for critical signal trace routing to be met.

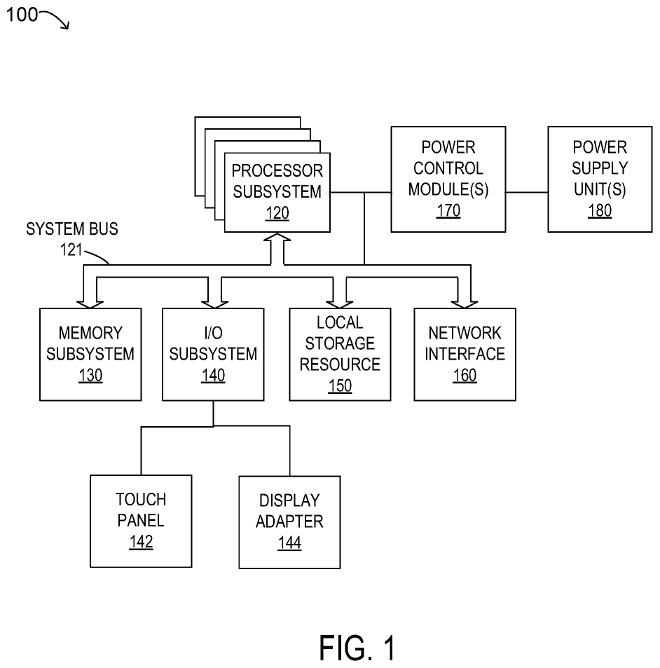

Particular embodiments are best understood by reference to FIGS. 1-5, where like numbers are used to indicate like and corresponding parts.

Turning now to the drawings, FIG. 1 illustrates a block diagram depicting selected elements of an embodiment of information handling system 100. As described herein, information handling system 100 may represent a personal computing device, such as a personal computer system, a desktop computer, a laptop computer, a notebook computer, etc., operated by a user. In various embodiments, information handling system 100 may be operated by the user using a keyboard and a mouse (not shown).

As shown in FIG. 1, components of information handling system 100 may include, but are not limited to, processor subsystem 120, which may comprise one or more processors, and system bus 121 that communicatively couples various system components to processor subsystem 120 including, for example, a memory subsystem 130, an I/O subsystem 140, local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

In FIG. 1, network interface 160 may be a suitable system, apparatus, or device operable to serve as an interface between information handling system 100 and a network (not shown). Network interface 160 may enable information handling system 100 to communicate over the network using a suitable transmission protocol and/or standard, including, but not limited to, transmission protocols and/or standards enumerated below with respect to the discussion of network 155. In some embodiments, network interface 160 may be communicatively coupled via the network to a network storage resource (not shown). The network coupled to network interface 160 may be implemented as, or may be a part of, a storage area network (SAN), personal area network (PAN), local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). The network coupled to network interface 160 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. The network coupled to network interface 160 and/or various components associated therewith may be implemented using hardware, software, or any combination thereof.

As depicted in FIG. 1, processor subsystem 120 may comprise a system, device, or apparatus operable to interpret and/or execute program instructions and/or process data, and may include a microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130). In the same or alternative embodiments, processor subsystem 120 may interpret and/or execute program instructions and/or process data stored remotely (e.g., in a network storage resource, not shown).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down. Local storage resource 150 may comprise computer-readable media (e.g., hard disk drive, floppy disk drive, CD-ROM, and/or other type of rotating storage media, flash memory, EEPROM, and/or another type of solid state storage media) and may be generally operable to store instructions and/or data. In system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. As shown, I/O subsystem 140 may comprise touch panel 142 and display adapter 144. Touch panel 142 may include circuitry for enabling touch functionality in conjunction with a display device that is driven by display adapter 144. It is noted that when information handling system 100 is a laptop computer with an integrated display device, display adapter 144 may provide connectivity for an external display.

As illustrated in FIG. 1, system 100 may include one or more power control modules 170 and one or more power supply units (PSUs) 180. In at least some embodiments, power control modules 170 may include power distribution circuitry. In at least some embodiments, power control module(s) 170 may control the allocation of power generated by one or more of the power supply units (PSUs) 180 to other resources in system 100. In some embodiments, one or more of the power control modules 170 may include a management controller (MC). In some embodiments, the management controller may include circuitry and/or logic to determine the operating capability of the PSUs 180 based on environmental or other factors. In some embodiments, the PSUs 180 may be coupled to an AC power source through a power adapter or power cable that includes a connector to information handling system 100 on one end and a power plug on the other end.

Although not specifically shown, system 100 may include one or more printed circuit boards (PCBs), according to one or more embodiments. For example, one or more components of system 100 may be implemented using hardware circuitry on one or more printed circuit boards. The hardware circuity may include components soldered onto the printed circuit board, as well as conductive traces etched into a conductive layer of the printed circuit board. For example, a printed circuit board may include multiple conductive layers, each comprising conductive traces for carrying current and traces for carrying data signals of various data signal types, including high-speed data signals. In various embodiments, the conductive layers may be distributed on respective sides of one or more substrate layers of the printed circuit board or between alternating substrate layers of the printed circuit board. For example, the PCB may be single-sided (including one copper layer), double-sided (including copper layers on both sides of one substrate layer), or multi-layered (including outer and inner layers of copper, alternating with layers of substrate). A printed circuit board may couple two or more devices to one-another. For example, the printed circuit board may include one or more traces that couple two or more devices to one-another. In some embodiments, traces in a first conductive layer may be coupled to traces in a second conductive layer using one or more vias. In at least some embodiments, power vias may deliver current to and between the conductive layers.

Some existing systems that include switching voltage regulators use many small round vias for large current energy delivery on the PCB power plane between two layers. For example, a large number of small round vias may be placed together and close to an integrated power-stage silicon chip to convey large amounts of current to other signal layers. In some embodiments, these small round vias may be the same as, or similar to, vias used for carrying data signals between PCB signal layers. The number of vias for each power-stage IC may be determined by the maximum sustainable current of each power-stage IC in accordance with design requirements. The more vias that are used together, the lower the voltage-drop between layers. This is because the equivalent resistance of the collection of vias decreases when more vias are used in parallel to deliver the current from the component layer to the other PCB layers. However, placing these vias together requires a relatively large area on the PCB through which critical traces cannot be routed on the inner layers. In addition, the trace routing cannot run too close to these vias because the switching behavior can induce large amounts of noise energy on these vias, potentially impacting the signal integrity of the adjacent signals.

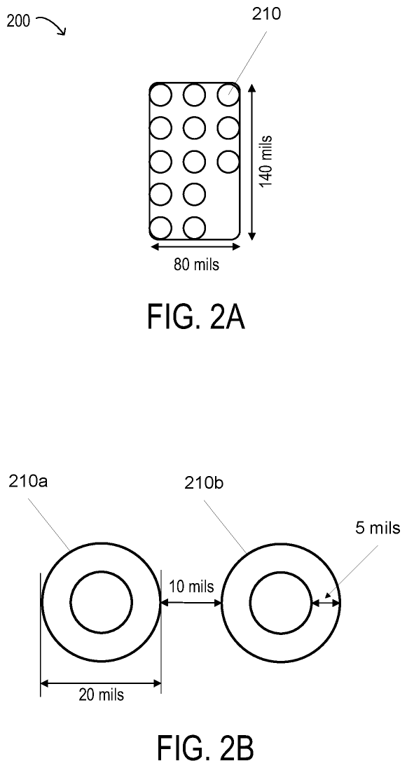

FIG. 2A is a block diagram illustrating selected elements of an example PCB layout 200 including an array of round, plated through vias 210, as described above. In this example, the array includes thirteen round, plated through vias 200 arranged in three columns and would occupy a footprint of 140 mils x 80 mils on a printed circuit board.

FIG. 2B illustrates an example layout design rule specifying the minimum spacing between a pair of adjacent, round, plated through vias, shown as vias 210a and 210b, within array 200. In the illustrated example, each of the round, plated through vias 210 has an outer diameter of 20 mils and a plating thickness of 5 mils. The minimum spacing between the two round, plated through vias 210 is 10 mils. When thirteen such round, plated through vias are arranged as in array 200 illustrated in FIG. 2A, in three columns separated by 10 mils and five rows separated by 10 mils, the footprint of the array covers an area measuring 140 mils by 80 mils.

In at least some embodiments of the present disclosure, a more space efficient layout of printed circuit board power vias may be achieved using a power via that has a flattened oval shape rather than an array or other collection of smaller, round vias. For example, a printed circuit board may include multiple conductive layers each comprising traces for carrying high-speed data signals, and a power via having a flattened oval shape for delivering current to and between the plurality of conductive layers. The power via may include an opening passing through the multiple conductive layers and the walls of the opening may be plated to a predetermined plating thickness using a conductive material to create a plated through via.

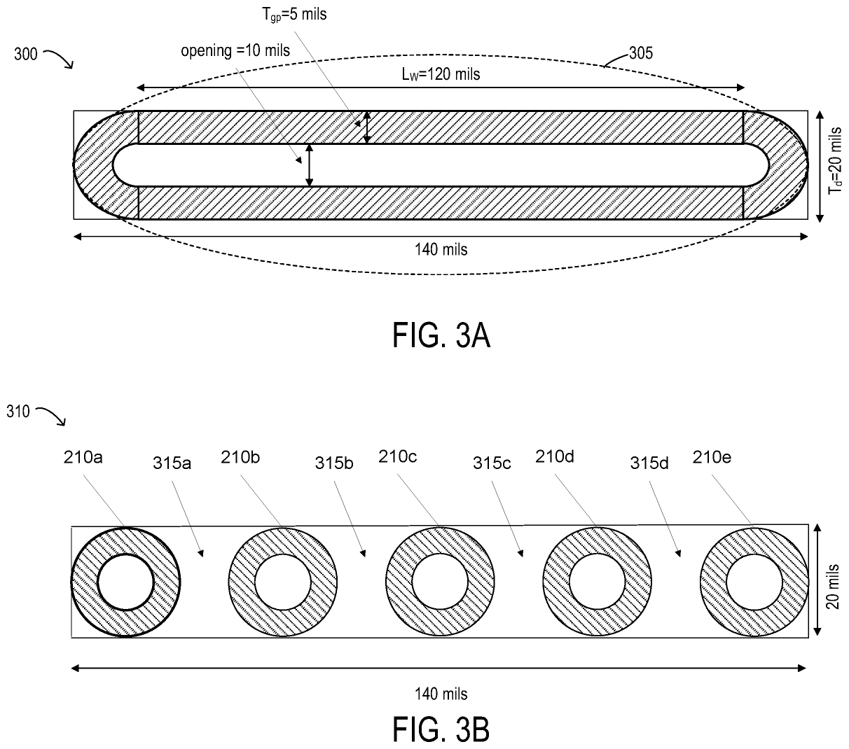

FIG. 3A is a block diagram illustrating an example power via with a flattened oval shape, according to some embodiments. In this example, the power via is a plated through via with a flattened oval shape in which, when the power via is viewed from a perspective perpendicular to a top-most one of the multiple conductive layers, two straight edges of the perimeter of the power via are parallel to a major axis of an elliptical shape 305 that encompasses the power via and are parallel to each other and the two ends of the perimeter of the power via that connect the two straight edges to each other on respective sides of the power via are rounded.

In at least some embodiments, the length of the power via along the major axis of the elliptical shape 305 that encompasses the power via may be greater than multiple times the width of the power via along the minor axis of the elliptical shape 305. For example, in one embodiment, the length of the power via along the major axis of the elliptical shape 305 that encompasses the power via may be approximately 140 mils, the width of the power via along the minor axis of the elliptical shape 305 may be approximately 20 mils, and the predetermined plating thickness may be approximately 5 mils, leaving a via opening that is approximately 10 mils wide in the center portion of the power via between the two straight edges.

FIG. 3B is a block diagram illustrating an example collection 310 of five round, plated through vias 210 in a printed circuit board. The collection 310 may represent one column of the round, plated through vias 210 of array 200 illustrated in FIGS. 2A and 2B. For example, each of the vias 210 may have a diameter of 20 mils and a plating thickness of 5 mils, and the spacing between adjacent vias 210 may be 10 mils. In this example, the plated through power via 300 shown in FIG. 3A has the same footprint as the collection 310 of five round, plated through vias 210, shown in FIG. 3B. For example, each has a footprint of 140 mils×20 mils. Note, however, that the areas between the round vias 210, shown as areas 315a through 315d, cannot be used for current and energy delivery, nor can critical or high-speed signal traces be routed through these areas.

In the illustrated example, power via 300 has a lower resistivity than the total equivalent resistivity of the five round, plated through vias 210 that, together with the required spacing between the round, plated through vias 210, collectively require the same amount of space on a printed circuit board as the plated through power via 300. In at least some embodiment, because of this lower resistance, power via 300 can sustain higher current delivery with less voltage-drop between different PCB layers than the collection 310 of five round, plated through vias 210. Therefore, as shown in this example, replacing the collection 310 of five round, plated through vias 210 in a PCB design with a flattened-oval-shaped power via 300 may yield multiple benefits in terms of lower resistively, the efficient use of space on the PCB, and/or increased routing options. In other embodiments, collections of multiple round vias of different sizes and having different arrangements may be replaced by corresponding flattened-oval-shaped power vias with equivalent resistivity and smaller footprints or with lower resistivity and the same footprints as the collections of round vias they replace. In still other embodiments, a flattened-oval-shaped power via that replaces a collection of multiple round vias in a PCB design may have both a lower resistivity and a smaller footprint than the collection of multiple round vias it replaces. The advantage of power via 300 over collection 310, in terms of resistivity, may be further illustrated by comparing a resistivity calculation for power via 300 and an equivalent resistivity calculation for the vias 210 of collection 310.

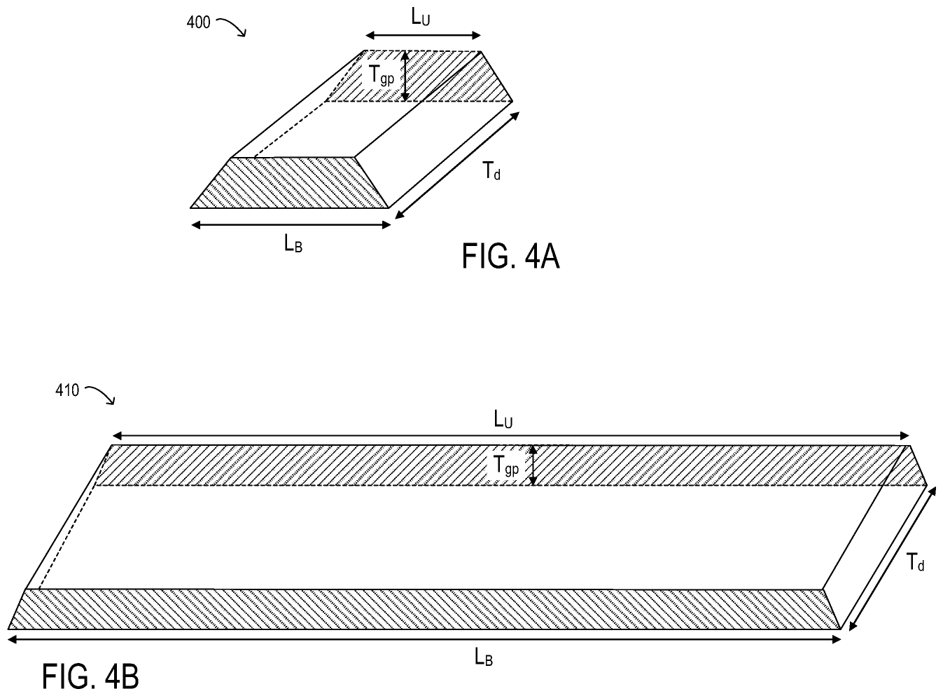

FIG. 4A illustrates a model 400 for estimating the resistivity of a single round, plated through via 210, which may then be used to estimate the equivalent resistance of the collection 310 of five round, plated through vias 210. Similarly, FIG. 4B illustrates a model 410 for estimating the resistivity of a plated through power via with a flattened oval shape, according to some embodiments. In these models, it is assumed that the PCB stackup thickness, T_{d}, in the case of power via 300 is identical to the PCB stackup thickness, T_{d}, in the case of collection 310. The resistivity estimates described herein are based on vias plated through a single substrate layer with conductive layers on both the top and bottom of the substrate. In practice, vias may be plated through a PCB stackup that includes multiple substrate layers and corresponding conductive layers, typically four or more layers including one or more inner conductive layers.

As shown in FIG. 4A, a trapezoidal column model 400 may be used to estimate the equivalent resistance of a round via with 20-mil diameter, and a 5-mil plating thickness, shown as T_{gp}. In model 400, the outer perimeter of the via is shown as LB and the inner perimeter of the via is shown as L_{U}, where L_{B}=20π and L_{U}=(20−5×2)×π=10π.

This trapezoidal column model 400 may be used to calculate the equivalent resistance of single via as in Equation 1 below. In Equation 1, A represents the trapezoidal area of a round via pad on the top and bottom PCB layers and p_{gp} represents the plating resistivity of the via. Equation 2 below shows that the trapezoidal area A in Equation 1 is 75π.

$$\begin{matrix}{R}_{round \_ via} = {ρ}_{gp} * \frac{{T}_{d}}{A} & ( Equation 1 ) \\ A = ( 10 π + 20 π ) * \frac{{T}_{gp}}{2} = 75 π , {T}_{gp} = 5 & ( Equation \text{-} 2 )\end{matrix}$$

Since the equivalent resistance R_{round_via} of single via 210, with a trapezoidal area A of 75π, is shown in Equation 1, using five round vias would enlarge the equivalent area to five times A, or 375π. Then the total equivalent resistance of five round vias may then be calculated as in Equation 3 below.

$${R}_{5 x \_ round \_ vias} = {ρ}_{gp} * \frac{{T}_{d}}{75 π * 5} = {ρ}_{gp} * \frac{{T}_{d}}{375 π} \qquad ( Equation 3 )$$

The trapezoidal column model 410 shown in FIG. 4B may be used to estimate the equivalent resistance of power via 300 using Equation 4 below. Here, A_{oval_via} represents the trapezoidal area of the power via 300, with its flattened oval shape, on the top and bottom layers of the printed circuit board, and ρ_{gp} represents the plating resistivity of the power via 300, which is assumed to be the same as for the single round via 210. In model 410, the outer perimeter of the power via 300 is shown as LB and the inner perimeter of the via is shown as L_{U}, where L_{B}=20π+(2×L_{W})=20π+240, and L_{U}=(20−5×2)×π+(2×L_{W})=10π+240. Equation 5 below shows that the trapezoidal area A_{oval_via} in Equation 4 is 75π+1200. Equation 6 shows that the total equivalent resistance of the collection 310 of five round vias 210 is 1.219 times greater than the resistance of power via 300 even though their footprints are identical.

$$\begin{matrix}{R}_{flat \_ oval \_ via} = {ρ}_{gp} * \frac{{T}_{d}}{{A}_{oval \_ via}} & ( Equation 4 ) \\ {A}_{oval \_ via} = ( 10 π + 240 + 20 π + 240 ) * \frac{{T}_{gp}}{2} = 75 π + 1200 , {T}_{gp} = 5 & ( Equation 5 ) \\ \frac{{R}_{5 x \_ round \_ vias}}{{R}_{flat \_ oval \_ via}} = \frac{{ρ}_{gp} * {T}_{d} \text{/} 375 π}{{ρ}_{gp} * {T}_{d} \text{/} ( 75 π + 1200 )} = \frac{75 π + 1200}{375 π} ≅ 1.219 & ( Equation 6 )\end{matrix}$$

In a second example (not shown in the figures), the resistivity of power via 300 may be compared to the total equivalent resistance of a collection of six round plated through vias 210, which would have a larger footprint than power via 300. In this example, Equation 7 below shows that the resistance of power via 300 is lower than the total equivalent resistance of a collection of six round, plated through vias 210 even though the footprint of power via 300 is smaller than the footprint of the collection of six round, plated through vias 210.

$$\frac{{R}_{6 x \_ round \_ vias}}{{R}_{flat \text{-} oval \text{-} via}} = \frac{{ρ}_{gp} * {T}_{d} \text{/} ( 75 π * 6 )}{{ρ}_{gp} * {T}_{d} \text{/} ( 75 π + 1200 )} = \frac{75 π + 1200}{75 π * 6} ≅ 1.015 \qquad ( Equation 7 )$$

These examples illustrate that a power via having a flattened oval shape may use layout space efficiently while delivering high current energy. For example, unlike collection 310 of round vias 210 with its wasted areas 315 between vias, there is no such wasted space in the flattened oval power via 300. The fact that there is no wasted space reduces the total equivalent resistance of power via 300, when compared to the collection 310 of round vias 210, to sustain higher current with the same layout space. For example, a flattened oval power via such as power via 300 may have a lower resistivity than a combined resistivity of a plurality of differently shaped plated through vias that, together with required spacing between the differently shaped plated through vias, collectively require the same footprint size as the flattened oval power via. In another example, the space occupied by a flattened oval power via such as power via 300 may be less than a required footprint size of a plurality of differently shaped plated through vias whose combined resistivity equals the resistivity of the flattened oval power via.

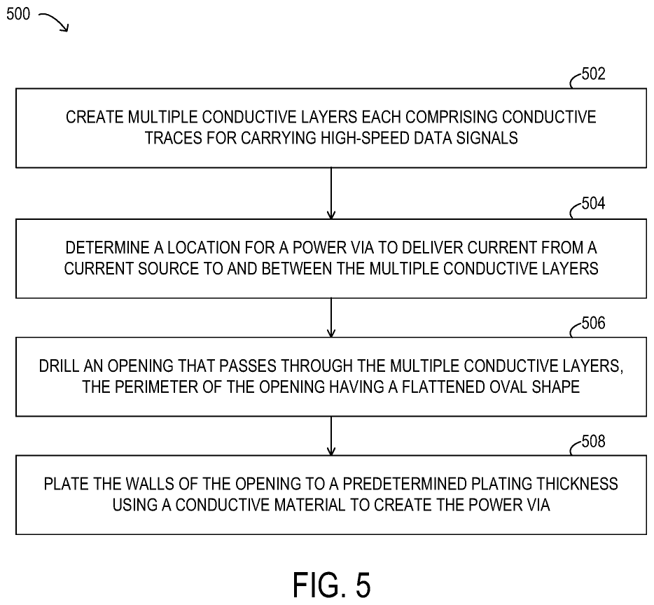

FIG. 5 is flow diagram depicting selected elements of an embodiment of a method 500 for manufacturing a printed circuit board, according to some embodiments. In some embodiments, method 500 may be performed as part of a method for manufacturing an information handling system. Method 500 may include more or fewer operations than those illustrated. Moreover, method 500 may execute its operations in an order different than those illustrated in FIG. 5. Method 500 may begin at any suitable operation and may terminate at any suitable operation. In some embodiments, method 500 may repeat any suitable operation. Furthermore, certain operations of method 500 may be executed multiple times, serially or in parallel, to create multiple power vias of a printed circuit board.

As depicted in FIG. 5, method 500 may begin (at 502) with creating multiple conductive layers for the printed circuit board, each comprising conductive traces for carrying high-speed data signals. In various embodiments, the multiple conductive layers may be distributed on respective sides of one or more substrate layers of the printed circuit board or between alternating substrate layers of the printed circuit board. For example, the printed circuit board may include a single-sided board including one conductive layer on a substrate, a double-sided board including a respective conductive layer on each of the two sides of a single substrate layer, or a multi-layer board including outer and inner conductive layers alternating with substrate layers. In at least some embodiments, the conductive layers may include copper that has been etched to create conductive traces for carrying current and for carrying data signals of various data signal types, including high-speed data signals.

Method 500 may include (at 504) determining a location for a power via to deliver current from a current source to and between the multiple conductive layers. In some embodiments, the source of the current delivered to and between the conductive layers may be a switched-mode power supply. In at least some embodiments, determining the location at which to create the power via on the printed circuit board may be dependent on predetermined minimum spacing rules for the layout of the printed circuit board. For example, the rules may specify a minimum distance between the power via and conductive traces carrying high-speed data signals, a minimum distance between the power via and conductive traces carrying data signals of signal types other than a high-speed data signal type, and/or a minimum distance between the power via and a particular functional element to be mounted on the printed circuit board proximate the power via. For example, the power via may be located at least as far from each of the conductive traces for carrying the high-speed data signals as a minimum distance defined by the minimum spacing rules for the layout of the printed circuit board. In some embodiments, determining the location at which to create the power via may include determining a location proximate an output capacitor of a voltage regulator on the printed circuit board or proximate a switched-mode power supply on the printed circuit board. For example, the power via may be located proximate an output capacitor of a voltage regulator on the printed circuit board.

At 506, the method may include drilling an opening that passes through the multiple conductive layers, where the perimeter of the opening has a flattened oval shape. For example, when the power via is viewed from a perspective perpendicular to a top-most one of the multiple conductive layers, two straight edges of the perimeter of the power via parallel to a major axis of an elliptical shape that encompasses the power via may be parallel to each other and the two ends of the perimeter of the power via that connect the two straight edges to each other on respective sides of the power via may be rounded. In some embodiments, the length of the power via along the major axis of the elliptical shape that encompasses the power via may be greater than or equal to twice the width of the power via along the minor axis of the elliptical shape. In one embodiment, the length of the power via along the major axis of the elliptical shape that encompasses the power via may be approximately 140 mils and the width of the power via along the minor axis of the elliptical shape that encompasses the power via may be approximately 20 mils.

At 508, method 500 may include plating the walls of the opening to a predetermined plating thickness using a conductive material to create the power via. In some embodiments, the predetermined plating thickness may be approximately 5 mils.

In at least some embodiments, prior to drilling the opening, the method may include aligning the multiple conductive layers and underlying substrates (not shown in FIG. 5). In such embodiments, drilling the opening may include drilling through the multiple conductive layers and underlying substrates in a single operation subsequent the aligning. Plating the walls of the opening may include plating through the opening that passes through the multiple conductive layers and substrates subsequent the aligning and drilling. In other embodiments, creating the plated through power via may include more, fewer, or different operations.

High density layout design is the market trend in high performance computing products. For example, in laptop computers, desktop computers, and server products, increasing numbers of integrated circuit components are included on a single PCB. The PCB may include a large number of traces to route critical high-speed data signals between these components. By including power vias with flattened oval shapes in the layout design of the PCB, the area on the PCB impacted by switching noise, for example, may be reduced compared to a layout design that includes arrays of smaller, round vias for carrying current to and between the PCB layers. In addition, the use of power vias with flattened oval shapes may reduce the number of PCB layers needed to solve routing issues on the PCB. In at least some embodiment, the techniques described herein may enable space efficient layout of printed circuit board power vias that are able to deliver high current energy.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A printed circuit board, comprising:
a plurality of conductive layers each comprising conductive traces for carrying high-speed data signals; and
a power via for delivering current to and between the plurality of conductive layers, wherein:
the power via comprises an opening passing through the plurality of conductive layers;
walls of the opening are plated to a predetermined plating thickness using a conductive material; and
the power via has a flattened oval shape in which, when the power via is viewed from a perspective perpendicular to a top-most one of the multiple conductive layers:
two straight edges of the perimeter of the power via are parallel to a major axis of an elliptical shape that encompasses the power via and are parallel to each other; and
two ends of the perimeter of the power via that connect the two straight edges to each other on respective sides of the power via are rounded.

2. The printed circuit board of claim 1, wherein the power via has a lower resistivity than a combined resistivity of a plurality of differently shaped plated through vias that, together with required spacing between the differently shaped plated through vias, collectively require a same footprint size as the power via.

3. The printed circuit board of claim 1, wherein space occupied by the power via is less than a required footprint size of a plurality of differently shaped plated through vias whose combined resistivity equals a resistivity of the power via.

4. The printed circuit board of claim 1, wherein the length of the major axis of the elliptical shape that encompasses the power via is greater than multiple times the length of a minor axis of the elliptical shape.

5. The printed circuit board of claim 1, wherein the power via is located at least as far from each of the conductive traces for carrying the high-speed data signals as a minimum distance defined by spacing rules for layout of the printed circuit board.

6. The printed circuit board of claim 1, wherein the plurality of conductive layers are distributed on respective sides of one or more substrate layers of the printed circuit board or between alternating substrate layers of the printed circuit board.

7. The printed circuit board of claim 1, wherein the power via is located proximate an output capacitor and one or more MOSFET devices of a voltage regulator on the printed circuit board.

8. The printed circuit board of claim 1, wherein a source of the current delivered to and between the plurality of conductive layers is a switched-mode power supply.

9. A method for manufacturing a printed circuit board, comprising:
creating multiple conductive layers each comprising conductive traces for carrying high-speed data signals; and
creating a power via for delivering current to and between the plurality of conductive layers, the creating including:
drilling an opening that passes through the plurality of conductive layers, the perimeter of the opening having a flattened oval shape in which, when the power via is viewed from a perspective perpendicular to a top-most one of the multiple conductive layers:
two straight edges of the perimeter of the power via are parallel to a major axis of an elliptical shape that encompasses the power via and are parallel to each other; and
two ends of the perimeter of the power via that connect the two straight edges to each other on respective sides of the power via are rounded; and
plating the walls of the opening to a predetermined plating thickness using a conductive material.

10. The method of claim 10, wherein the plurality of conductive layers are distributed on respective sides of one or more substrate layers of the printed circuit board or between alternating substrate layers of the printed circuit board.

11. The method of claim 10, wherein:
creating the power via further comprises, prior to drilling the opening, aligning the plurality of conductive layers;
drilling the opening comprises drilling through the plurality of conductive layers subsequent the aligning; and
plating the walls of the opening comprises plating through the opening that passes through the plurality of conductive layers subsequent the drilling.

12. The method of claim 10, wherein the power via has a lower resistivity than a combined resistivity of a plurality of differently shaped plated through vias that, together with required spacing between the differently shaped plated through vias, collectively require a same footprint size as the power via.

13. The method of claim 10, wherein space occupied by the power via is less than a required footprint size of a plurality of differently shaped plated through vias whose combined resistivity equals a resistivity of the power via.

14. The method of claim 10, further comprising, prior to creating the power via, determining a location at which to create the power via on the printed circuit board dependent on predetermined minimum spacing rules for layout of the printed circuit board, the rules specifying one or more of:
a minimum distance between the power via and conductive traces carrying high-speed data signals;
a minimum distance between the power via and conductive traces carrying data signals of signal types other than a high-speed data signal type; and
a minimum distance between the power via and a functional element to be mounted on the printed circuit board proximate the power via.

15. The method of claim 14, wherein the predetermined minimum spacing rules specify a minimum distance between the power via and conductive traces carrying high-speed data signals that is greater than a specified minimum distance between the power via and conductive traces carrying data signals of signal types other than a high-speed data signal type.

16. The method of claim 14, wherein determining the location at which to create the power via comprises determining a location proximate an output capacitor and one or more MOSFET devices of a voltage regulator on the printed circuit board or proximate a switched-mode power supply on the printed circuit board.

17. An information handling system, comprising:
a power supply unit; and
a printed circuit board, comprising:
a plurality of conductive layers each comprising conductive traces for carrying high-speed data signals; and
a power via for delivering current from the power supply unit to and between the plurality of conductive layers, wherein:
the power via comprises an opening passing through the plurality of conductive layers;
walls of the opening are plated to a predetermined plating thickness using a conductive material; and
the power via has a flattened oval shape in which, when the power via is viewed from a perspective perpendicular to a top-most one of the multiple conductive layers:
two straight edges of the perimeter of the power via are parallel to a major axis of an elliptical shape that encompasses the power via and are parallel to each other; and
two ends of the perimeter of the power via that connect the two straight edges to each other on respective sides of the power via are rounded.

18. The information handling system of claim 17, wherein the power via has a lower resistivity than a combined resistivity of a plurality of differently shaped plated through vias that, together with required spacing between the differently shaped plated through vias, collectively require a same footprint size as the power via.

19. The information handling system of claim 17, wherein space occupied by the power via is less than a required footprint size of a plurality of differently shaped plated through vias whose combined resistivity equals a resistivity of the power via.

20. The information handling system of claim 17, wherein the power via is located proximate an output capacitor and one or more MOSFET devices of a voltage regulator on the printed circuit board or proximate a switched-mode power supply on the printed circuit board.
